(19) United States
(12) Patent Application Publication
(10) Pub. No.: US 2022/0357398 A1
(43) Pub. Date: Nov. 10, 2022

(54) MAINTENANCE METHOD AND MAINTENANCE PROGRAM FOR ENERGY STORAGE APPARATUS

(71) Applicant: GS Yuasa International Ltd., Kyoto (JP)

(72) Inventors: Toshihiro YABU, Kyoto (JP); Yoshiyuki INOUE, Kyoto (JP)

(21) Appl. No.: 17/626,943

(22) PCT Filed: Jun. 22, 2020
(86) PCT No.: PCT/JP2020/024292

§ 371 Date: Jan. 13, 2022

(30) Foreign Application Priority Data
Jul. 18, 2019 (JP) 2019-132698

(51) Int. Cl. G01R 31/367; G01R 31/3835; H01M 10/48; H01M 50/509; H01M 10/42

(52) U.S. Cl. CPC G01R 31/367; G01R 31/3835; H01M 10/482; H01M 50/509; H01M 10/425; H01M 2010/4271

(57) ABSTRACT

A maintenance method for a power storage device 1 in which a plurality of power storage units 9 in which a plurality of battery cells 11 are connected in series are connected in parallel. The maintenance method includes a comparison step for comparing log data for battery cells 11 that are at the same series connection positions in the power storage units 9 and a determination step for determining, on the basis of comparison results from the comparison step, the power storage unit 9 at which an abnormality has occurred.

### CROSS REFERENCE TO RELATED APPLICATIONS

This application is a national stage application, filed under 35 U. S.C. § 371, of International Application No. PCT/JP2020/024292, filed Jun. 22, 2020, which international application claims priority to and the benefit of Japanese Application No. 2019-132698, filed Jul. 18, 2019, the contents of both of which as are hereby incorporated by reference in their entireties.

### BACKGROUND

### Technical Field

This specification discloses a technique related to a maintenance method and a maintenance program for an energy storage apparatus.

### Description of Related Art

Conventionally, there has been known an energy storage apparatus including a plurality of energy storage devices (or energy storage modules). The energy storage apparatus stores log data of the energy storage devices or energy storage modules (see, for example, Patent Document JP-A-2015-050819). Patent Document JP-A-2015-050819 specifically discloses a system where log information (log data) including usage history information for each of the energy storage modules is stored in a log storage memory provided in the corresponding energy storage module and in a log storage memory provided in an apparatus that charges or discharges each of the energy storage modules. Patent Document JP-A-2015-050819 discloses the system where the log information is acquired from the log storage memories, and based on the log information acquired, the usage history information for each of the energy storage modules is held in a database to be controlled.

As in the above, Patent Document JP-A-2015-050819 discloses a technique configured to acquire the log information including the usage history information. In addition, a voltage value, a current value, a temperature value, a state of charge (SOC), and others are also conventionally acquired as the log data.

### BRIEF SUMMARY

There are large scale energy storage apparatuses including a large number of energy storage devices (or energy storage modules). Such a large scale energy storage apparatus is, for example, a port/harbor automatic guided vehicle (AGV) as an unmanned vehicle to carry a container at a port/harbor. Some of the port/harbor AGVs travel by electric motors. A port/harbor AGV of this type has a large scale energy storage apparatus mounted thereto, and the large scale energy storage apparatus is configured to supply power to the electric motor. As another example, a large scale energy storage apparatus is provided to a power supply system that is installed to supply power in a mountainous area, a remote island, or others.

In some cases, a problem occurs with the energy storage apparatus due to an anomaly in the energy storage devices or the energy storage modules. A flow of steps to follow (troubleshooting) at occurrence of the problem is, for example, as follows. An apparatus manager of the energy storage apparatus reports the problem to a manufacturer of the energy storage apparatus. On reception of the report, a serviceman is dispatched from the manufacturer to analyze the log data (e.g., the voltage value, the current value, the temperature value and the SOC) for the energy storage devices (or energy storage modules), based on which the serviceman is to presume a cause for the problem.

However, with a tendency for larger size of the energy storage apparatus, an amount of the log data stored is significantly large, thereby increasing time required for analysis of the log data. For example, an energy storage apparatus mounted to a port/harbor AGV includes ten energy storage units that are connected in parallel to each other, and each of the ten energy storage units includes fifteen energy storage modules that are connected in series. Further, each of the fifteen energy storage modules includes twelve energy storage devices that are connected in series; and thus, each of the ten energy storage units includes 180 energy storage devices, thereby resulting in the energy storage apparatus including 1,800 energy storage devices. The log data per day has a size often megabytes for each of the energy storage units. When each of the energy storage devices is a lithium ion battery, for example, in order to reliably prevent overcharge or overdischarge, monitoring for all of the energy storage devices is required. Typically, each of the energy storage units includes one current sensor, one to several temperature sensor(s), and voltage sensors, the number of which is as many as the energy storage devices (i.e., 180). These sensors acquire data, for example, every one to fifteen seconds. Particularly, the voltage value, the current value, and the SOC occupy a major part of the data.

With this configuration, from when the problem occurs until when the cause for the problem is presumed, considerable time is required. Even when the cause is minor and thus it is possible to immediately restore the energy storage apparatus, time is still required for presuming the cause, thereby leading to a prolonged suspension of the energy storage apparatus. Further, in a case where the serviceman from the manufacturer has insufficient knowledge and/or experience, the cause may be wrongly presumed. Consequently, after-service quality may be degraded.

Accordingly, a large scale energy storage apparatus has, as particular difficulties, two issues as follows.

First issue: A large scale energy storage apparatus includes a significantly large number of energy storage devices (or energy storage modules) to be monitored; and thus, knowledge and experience are required to presume the cause for the problem.

Second issue: An energy storage apparatus as an infrastructure is required to be restored at the earliest possible time.

This specification discloses a technique with which, when some problem occurs with a large scale energy storage apparatus, it is highly possible to restore the large scale energy storage apparatus in speedy manner regardless of the knowledge or experience of the serviceman.

Provided is a maintenance method for an energy storage apparatus including a plurality of energy storage units that are connected in parallel to each other, each of the energy storage units including a plurality of energy storage devices that are connected in series. The maintenance method includes: a comparison step of comparing log data for one of the energy storage devices in each of the energy storage units, which is at a same sequential order of series connection; and a determination step of, based on a comparison result of the comparison step, determining which one of the energy storage units has an anomaly.

With the configuration described above, when some problem occurs with a large scale energy storage apparatus, it is highly possible to restore the large scale energy storage apparatus in speedy manner, regardless of knowledge or experience of a serviceman.

### BRIEF DESCRIPTION OF THE FIGURES

FIG. 1 is a schematic diagram of an energy storage apparatus according to a first embodiment.

FIG. 2 is a block diagram of an energy storage module and a battery management unit (BMU).

FIG. 3 is a schematic diagram showing an example of log data.

FIG. 4 is a schematic diagram illustrating a flow of steps to follow at occurrence of a problem with the energy storage apparatus.

FIG. 5 is a schematic diagram showing a configuration of folders in a personal computer (PC).

FIG. 6 is a schematic diagram illustrating a set screen.

FIG. 7 is a schematic diagram illustrating a graph screen (no part of which is enlarged).

FIG. 8 is a schematic diagram illustrating a graph screen (as an enlarged part of the graph screen in FIG. 7).

FIG. 9 is a schematic diagram illustrating a graph screen (where a part of the graph is hidden).

FIG. 10 is a schematic diagram showing an example of the log data written to a comma-separated values (CSV) file for data output.

### DETAILED DESCRIPTION OF VARIOUS EMBODIMENTS

(Summary of this Embodiment)

(1) Provided is a maintenance method for an energy storage apparatus including a plurality of energy storage units that are connected in parallel to each other, each of the energy storage units including a plurality of energy storage devices that are connected in series. The maintenance method includes: a comparison step of comparing log data for one of the energy storage devices in each of the energy storage units, which is at a same sequential order of series connection; and a determination step of, based on a comparison result of the comparison step, determining which one of the energy storage units has an anomaly.

With an energy storage apparatus including a plurality of energy storage units that are connected in parallel to each other, each of the plurality of energy storage units including a plurality of energy storage devices that are connected in series, the inventors of the present application have identified tendencies as follows.

When every energy storage devices are normal, one of the energy storage devices (in one of the energy storage units) exhibits an identical behavior to the energy storage devices (in the other energy storage units), each of which is at the same sequential order of series connection. When one of the energy storage devices in one of the energy storage units has an anomaly, it is rare that only the abnormal one of the energy storage devices exhibits a different behavior from the other energy storage devices, each of which is at the same sequential order of series connection. In this state, all the other ones of the energy storage devices belonging to the same energy storage unit are also prone to exhibit different behaviors from the other energy storage devices that are respectively at the same sequential orders of series connections.

For example, in each of the energy storage units, 180 energy storage devices are connected in series. Let's assume that a 180th energy storage device in one of the energy storage units has an anomaly. In this case, it is rare that only the 180th energy storage device in the one energy storage unit exhibits a different behavior from 180th energy storage devices in the other energy storage units. Here, the other normal energy storage devices (a 1st energy storage device to a 179th energy storage device) in the one energy storage unit are also prone to respectively exhibit different behaviors in the other energy storage units that are respectively at the same sequential orders of series connections. The reason for the above will be described below.

As an example, when a voltage of each of the energy storage devices at a certain time is 3.9 V, a total voltage of each of the energy storage units corresponds to 3.9×180=702 V. When all of the energy storage devices are normal, the energy storage units exhibit no difference in the total voltage 702 V. In this state, when the energy storage devices are discharged, each of the energy storage units is discharged at the same current value; and the total voltage (i.e., the voltages of the energy storage devices) in each of the energy storage units tends to decrease in the same manner. Here, when one of the energy storage devices in an energy storage unit Ua becomes abnormal and the voltage of the abnormal energy storage device changes from 3.9 V to 3.0 V, a total voltage of Ua corresponds to 3.9×179+3.0=701.1 V. When energy storage units Ub and Uc are normal, and when the energy storage units Ua, Ub, and Uc are discharged in this state, the energy storage units Ub and Uc exhibit the total voltages higher than that of the energy storage unit Ua. Thus, a larger amount of current flows in the energy storage units Ub and Uc until the total voltages becomes the same as that of Ua. The energy storage device Ua is smaller in discharge current than Ub and Uc, so that the total voltage (i.e., the voltages of the energy storage devices) in the energy storage unit Ua tends to decrease in a different manner from Ub and Uc. With this configuration, even a normal one of the energy storage devices in the energy storage unit (that includes the abnormal energy storage device) also exhibits an abnormal tendency as compared with energy storage devices in the other energy storage units, which are at the same sequential order of series connection as the normal one.

Accordingly, as a temporary analysis at occurrence of a problem with the energy storage apparatus, the log data for the energy storage devices, which are respectively at the same sequential order of series connection in the energy storage units, are compared; and as a result, the energy storage unit, which includes the abnormal energy storage device (hereinafter, simply referred to as an “energy storage unit where an anomaly has occurred”), is identified.

With the maintenance method described above, instead of going through an analysis of each individual one of the log data for a large number of the energy storage devices, by comparing the log data for the energy storage devices that are respectively at the same sequential order of series connection in the energy storage units, it is possible to identify, based on a small amount of log data, the energy storage unit where the anomaly has occurred. Accordingly, even when the serviceman is not very experienced or knowledgeable, it is possible to identify the energy storage unit where the anomaly has occurred at high accuracy and in speedy manner. Having identified the energy storage unit where the anomaly has occurred at high accuracy and in speedy manner, it is possible to proceed without delay to the subsequent detailed analysis. With the maintenance method described above, when some problem occurs with a large scale energy storage apparatus, it is highly possible to restore the energy storage apparatus in speedy manner, regardless of the knowledge or experience of the serviceman.

(2) Provided is a maintenance method for an energy storage apparatus including a plurality of energy storage units that are connected in parallel to each other, each of the energy storage units including a plurality of energy storage modules that are connected in series. The maintenance method includes: a comparison step of comparing log data for one of the energy storage modules in each of the energy storage units, which is at a same sequential order of series connection; and a determination step of, based on a comparison result of the comparison step, determining which one of the energy storage units has an anomaly.

As with the case of the energy storage device, as a temporary analysis at occurrence of a problem with the energy storage apparatus, log data for the energy storage modules, which are respectively at the same sequential order of series connection in the energy storage units, are compared; and as a result, the energy storage unit, which includes an abnormal energy storage module (hereinafter, simply referred to as an “energy storage unit where an anomaly has occurred”), is identified.

With the maintenance method described above, instead of going through an analysis of each individual one of the log data for a large number of the energy storage modules, by comparing the log data for the energy storage modules that are respectively at the same sequential order of series connection in the energy storage units, it is possible to identify, based on a small amount of log data, the energy storage unit where the anomaly has occurred. Accordingly, even when the serviceman is not very experienced or knowledgeable, it is possible to identify the energy storage unit where the anomaly has occurred at high accuracy and in speedy manner. Having identified the energy storage unit where the anomaly has occurred at high accuracy and in speedy manner, it is possible to proceed without delay to the subsequent detailed analysis. With the maintenance method described above, when some problem occurs with a large scale energy storage apparatus, it is highly possible to restore the energy storage apparatus in speedy manner, regardless of the knowledge or experience of the serviceman.

(3) The energy storage apparatus may store the log data in a storage medium, and in the comparison step, the log data stored in the storage medium may be compared with each other.

In many cases, a movable system such as a port/harbor AGV is not provided with a communication function. When the movable system without any communication function has an energy storage apparatus mounted thereto, it is not possible to remotely monitor the energy storage apparatus. When the energy storage apparatus is provided to a power supply system installed in a mountainous area, a remote island, or others, due to a poor radio environment, it is difficult in many cases to remotely monitor the energy storage apparatus at all times.

Thus, such an energy storage apparatus typically stores the log data in the storage medium. When some problem occurs, the serviceman is dispatched from the manufacturer to a field site (site where the energy storage apparatus is installed) to analyze the log data stored in the storage medium. However, as has been previously described, the amount of the log data is significantly large. When the serviceman is not very experienced or knowledgeable, it is difficult to identify the energy storage unit where the anomaly has occurred on the field, at high accuracy, and in speedy manner.

With the maintenance method described above, despite difficulty in monitoring the energy storage apparatus remotely, and even when the serviceman is not very experienced or knowledgeable, it is highly possible to identify the energy storage unit where the anomaly has occurred on the field, at high accuracy, and in speedy manner. Accordingly, the maintenance method is suitably applied to an energy storage apparatus, in a situation where it is difficult to remotely monitor the energy storage apparatus.

(4) The maintenance method may further include a transmission step of transmitting to a maintenance department the log data for the one of the energy storage devices in each of the energy storage units, which is at the same sequential order of series connection.

When the energy storage apparatus is installed to the port/harbor AGV or installed in the mountainous area, the remote island, or others, conventionally, the serviceman is dispatched from the manufacturer to the field to presume an abnormal energy storage device based on the log data stored in the storage medium. However, in some cases, the serviceman, having presumed multiple causes, struggles to presume on the field the abnormal energy storage device. In this case, conventionally, the serviceman transmits the log data to the maintenance department of the manufacturer, so that the maintenance department analyzes the log data. However, as has been previously described, the amount of the log data is significantly large, thereby requiring time to transmit the log data.

With the maintenance method described above, the serviceman transmits to the maintenance department the log data for the energy storage devices at the same sequential order of series connections. Thus, the log data transmitted here is smaller in amount than all the log data. Additionally, the serviceman transmits to the maintenance department only the log data to be analyzed, thereby facilitating the maintenance department to provide more efficient performances. Accordingly, it is highly possible to restore the energy storage apparatus in speedy manner.

(5) The maintenance method may further include a transmission step of transmitting to the maintenance department the log data for the one of the energy storage modules in each of the energy storage units, which is at the same sequential order of series connection.

With the maintenance method described above, the serviceman transmits to the maintenance department the log data for the energy storage modules at the same sequential order of series connections. Thus, the log data transmitted here is smaller in amount than all the log data. Additionally, the serviceman transmits to the maintenance department only the log data to be analyzed, thereby facilitating the maintenance department to provide more efficient performances. Accordingly, it is highly possible to restore the energy storage apparatus in speedy manner.

(6) Provided is a maintenance program for an energy storage apparatus including a plurality of energy storage units that are connected in parallel to each other, each of the energy storage units including a plurality of energy storage devices that are connected in series. The maintenance program causes a computer to execute: an extraction step of, from log data for each of the energy storage devices in each of the energy storage units, extracting log data for one of the energy storage devices at a predetermined sequential order of series connection or a specified sequential order of series connection; and an output step of outputting the log data that has been extracted in the extraction step.

The “predetermined sequential order of series connection” corresponds to, for example, a sequential order of series connection fixed and set previously in the maintenance program. The “specified sequential order of series connection” corresponds to, for example, a sequential order of series connection specified by a user (e.g., a serviceman) of the maintenance program.

With the maintenance program described above, instead of going through an analysis of each individual one of the log data for a large number of the energy storage devices, the serviceman compares the log data for the energy storage devices that are respectively at the same sequential order of series connection in the energy storage units. With this configuration, the serviceman identifies, based on a small amount of log data, the energy storage unit where the anomaly has occurred. Accordingly, even when the serviceman is not very experienced or knowledgeable, it is possible to identify the energy storage unit where the anomaly has occurred at high accuracy and in speedy manner. Having identified the energy storage unit where the anomaly has occurred at high accuracy and in speedy manner, it is possible to proceed without delay to the subsequent detailed analysis. With the maintenance program described above, when some problem occurs with a large scale energy storage apparatus, it is highly possible to restore the energy storage apparatus in speedy manner, regardless of the knowledge or experience of the serviceman.

(7) Provided is a maintenance program for an energy storage apparatus including a plurality of energy storage units that are connected in parallel to each other, each of the energy storage units including a plurality of energy storage modules that are connected in series. The maintenance program causes a computer to execute: an extraction step of, from log data for each of the energy storage modules in each of the energy storage units, extracting log data for one of the energy storage modules at a predetermined sequential order of series connection or a specified sequential order of series connection; and an output step of outputting the log data that has been extracted in the extraction step.

With the maintenance program described above, instead of going through an analysis of each individual one of the log data for a large number of the energy storage modules, the serviceman compares the log data for the energy storage modules that are respectively at the same sequential order of series connection in the energy storage units. With this configuration, the serviceman identifies, based on a small amount of log data, the energy storage unit where an anomaly has occurred. Accordingly, even when the serviceman is not very experienced or knowledgeable, it is possible to identify the energy storage unit where the anomaly has occurred at high accuracy and in speedy manner. Having identified the energy storage unit where the anomaly has occurred at high accuracy and in speedy manner, it is possible to proceed without delay to the subsequent detailed analysis. With the maintenance program described above, when some problem occurs with a large scale energy storage apparatus, it is highly possible to restore the energy storage apparatus in speedy manner, regardless of the knowledge or experience of the serviceman.

(8) The log data may correspond to a voltage value.

The inventors of the present application have found out that by comparing the voltage values of the energy storage devices or the voltage values of the energy storage modules, it is possible to identify at high accuracy the energy storage unit where the anomaly has occurred.

Typically, instantaneous values are stored as the log data at time interval of several seconds to ten and several minutes; and thus, at some timings of comparing the log data, a current value that is prone to fluctuate may cause a normal one of the energy storage devices or a normal one of the energy storage modules to be regarded as abnormal. Additionally, a temperature value has a small amount of change; and thus, it is difficult to determine whether a difference in temperature is caused by an environmental factor or an abnormal one of the energy storage devices/the energy storage modules, thereby leading to a failure to identify the anomaly. On the other hand, at normal times, the voltage value is smaller in amount of instantaneous change than the current value and thus, the log data is less prone to vary according to the timing of comparing the log data. Normally, the voltage value varies only when some anomaly has occurred and thus, it is easier to determine whether the condition is normal or not based on the voltage value, rather than based on the current value or the temperature value.

(9) The output step may correspond to a step of displaying on a display unit the log data that has been extracted in the extraction step.

With the maintenance method described above, the log data is displayed, thereby clearly showing a difference between the log data for a normal one and the log data for an abnormal one. For example, when the log data for each of the energy storage devices or each of the energy storage modules is displayed in a graph, the log data for the abnormal energy storage device or the abnormal energy storage module clearly shows the difference from the log data for the normal energy storage devices or the normal energy storage modules. With this configuration, it is easier to identify the energy storage unit where the anomaly has occurred at high accuracy and in speedy manner.

(10) The maintenance program further causes the computer to execute a switch step of switching between display and hiding of log data selected from the log data that has been displayed on the display unit.

With the maintenance program described above, by switching between the display and the hiding of the log data for the energy storage device selected or the log data for the energy storage module selected, it is easier to identify the energy storage unit where the anomaly has occurred at high accuracy and in speedy manner.

(11) The output step may correspond to a step of writing to a file the log data that has been extracted in the extraction step.

When the energy storage apparatus is installed to the port/harbor AGV or installed in the mountainous area, the remote island, or others, conventionally, the serviceman is dispatched from the manufacturer to the field to presume an abnormal energy storage device based on the log data stored in the storage medium. However, in some cases, the serviceman, having presumed multiple causes, struggles to presume on the field the abnormal energy storage device. In this case, conventionally, the serviceman transmits the log data to the maintenance department of the manufacturer, so that the maintenance department analyzes the log data. However, as has been previously described, the amount of the log data is significantly large, thereby requiring time to transmit the log data.

With the maintenance method described above, the log data that has been extracted is written to the file for data output and transmitted to the maintenance department. Thus, the data transmitted here is reduced in amount. Accordingly, it is highly possible to restore the energy storage apparatus in speedy manner.

The present invention disclosed in this specification may be provided in various aspects, such as an apparatus, a method, a computer program to cause the apparatus or the method to function, or a storage medium for storing the computer program.

<First Embodiment>

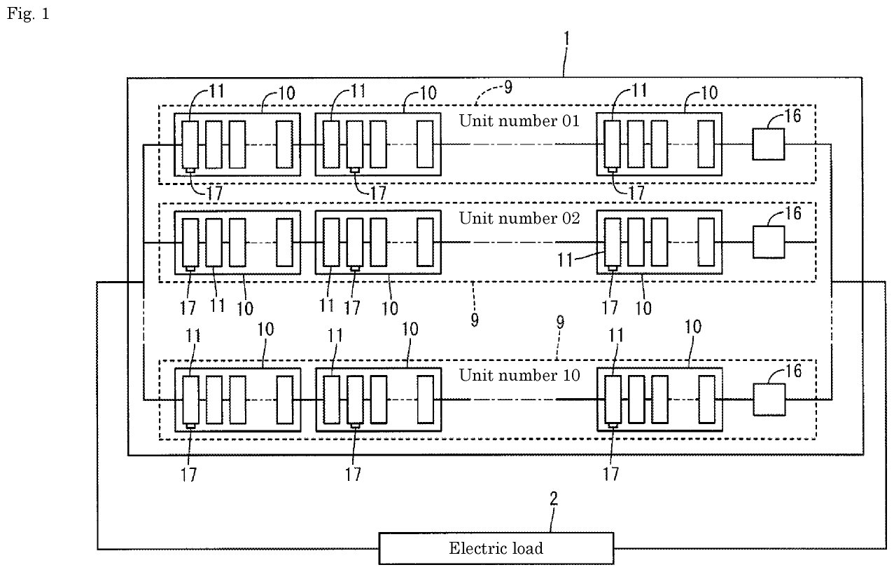

A first embodiment will be described with reference to FIGS. 1 to 10. Note that, with regard to reference signs in the drawings, some of the reference signs for identical constituent members may be omitted in descriptions below.

(1) Energy Storage Apparatus

An overall configuration of an energy storage apparatus 1 according to the first embodiment will be described with reference to FIG. 1. The energy storage apparatus 1 corresponds to a large scale energy storage apparatus mounted to a port/harbor AGV and configured to supply power to an electric load 2 (an electric motor for the port/harbor type AGV). The energy storage apparatus 1 does not have a function to communicate via a communication network. Thus, it is not possible to remotely monitor the energy storage apparatus 1.

The energy storage apparatus 1 includes ten energy storage units 9 that are connected in parallel to each other, and each of the ten energy series units 9 includes fifteen energy storage modules 10 that are connected in series. Each of the ten energy storage units 9 is provided with one of unit numbers 01 to 10. Each of the fifteen energy storage modules 10 includes twelve battery cells 11 (each as an example of an energy storage device) that are connected in series. With this configuration, the energy storage apparatus 1 includes a total of 1,800 battery cells 11.

Each of the ten energy storage units 9 includes a battery management system (BMS) as will be described later. Each of the BMSs is configured to manage the corresponding energy storage unit 9.

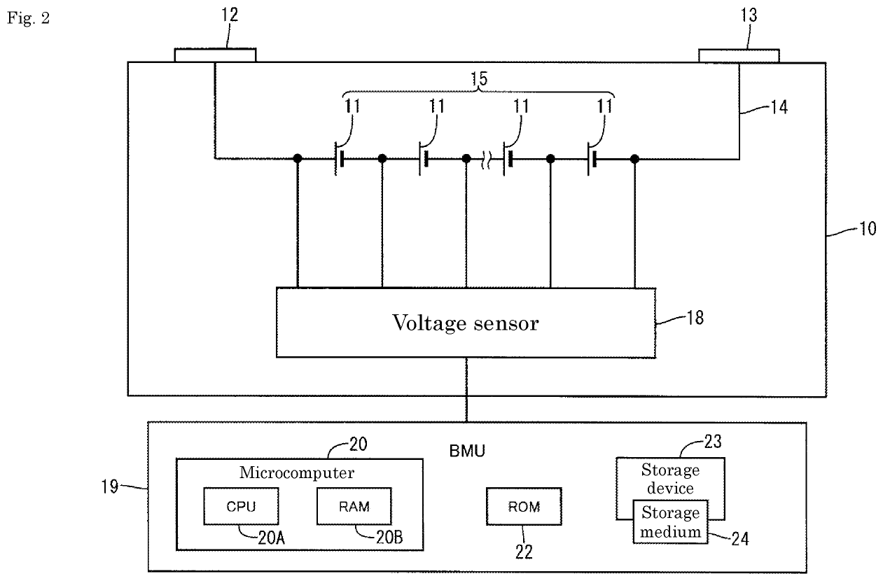

Each of the energy storage modules 10 will be described with reference to FIG. 2. Each of the energy storage modules 10 includes a positive electrode external terminal 12, a negative electrode external terminal 13, a main circuit 14, and the twelve battery cells 11. The positive external terminal 12 and the negative external terminal 13 are connected via the main circuit 14, and the twelve battery cells 11 are connected in series to the main circuit 14. Each of the twelve battery cells 11 is a nonaqueous electrolyte secondary battery and more specifically, for example, a lithium ion battery. In the descriptions below, the twelve battery cells 11, which are connected in series, will be referred to as an assembled battery 15.

Each of the BMSs will be described with reference to FIGS. 1 and 2. Each of the BMSs includes a current sensor 16 and a temperature sensor 17 as illustrated in FIG. 1, together with a voltage sensor 18 and a battery management unit (BMU) 19 as illustrated in FIG. 2.

As illustrated in FIG. 1, each of the energy storage units 9 includes the current sensor 16, the number of which is one. The current sensor 16 is connected in series to the energy storage modules 10, and is configured to measure a charge-discharge current of the corresponding energy storage unit 9 and output the charge-discharge current measured to the BMU 19.

Each of the energy storage units 9 also includes the temperature sensor 17, the number of which is one to several. Each of the temperature sensors 17 is provided to a different one of the battery cells 11, and is configured to measure a temperature of the corresponding battery cell 11 and output the temperature measured to the BMU 19.

As illustrated in FIG. 2, each of the energy storage modules 10 includes the voltage sensor 18. The voltage sensor 18 is connected in parallel with each of the battery cells 11, and is configured to measure voltage between both ends of the corresponding battery cell 11 and output the voltage measured to the BMU 19.

Each of the energy storage units 9 includes the BMU 19, the number of which is one, and the BMU 19 is configured to manage the fifteen energy storage modules 10 of the corresponding energy storage unit 9. For convenience of description, FIG. 2 illustrates only one of the energy storage modules 10.

Each of the BMUs 19 includes a microcomputer 20 as a central processing unit (CPU) 20A, a random-access memory (RAM) 20B, or others incorporated into a single chip, a read-only memory (ROM) 22, a storage device 23, and others. The ROM 22 stores various control programs, data, and others. The microcomputer 20 executes the various control programs stored in the ROM 22 to control the energy storage modules 10. The storage device 23 is configured to write data to a storage medium 24 as a removable, non-volatile medium. The storage medium 24 as the removable, non-volatile medium corresponds to a non-volatile semiconductor memory (typically-called memory card), a portable hard disk drive, or others.

The storage medium 24 is not necessarily designed to be removable. For example, when the energy storage apparatus 1 includes a communication connector such as a universal serial bus (USB) connector, the data stored in the storage medium 24 may be configured to be read via a communication cable connected to the communication connector.

The sensors (the current sensor 16, the temperature sensor 17, and the voltage sensor 18) are configured to respectively measure measurement value (the current value, the temperature value, and the voltage value of the battery cells 11) at predetermined time intervals, every one to fifteen seconds, and output these values measured to the BMU 19. The BMU 19 receives information outputted from each of the sensors, the information including the values measured, voltage between both ends of the assembled battery 15 (a total of the voltages of the twelve battery cells 11), alarm information and others. Then, the BMU 19 writes the information received to the storage medium 24 as log data. The alarm information includes occurrences of low voltage, overcurrent, high temperature, or others. The alarm information varies approximately as many as twenty types.

Further, whenever the current value is measured, the BMU 19 presumes the SOC of the corresponding energy storage unit 9 based on a current integration method, and write the SOC presumed to the storage medium 24 as the log data. Here, the SOC is presumed based on the current integration method, but the method to presume the SOC is not limited thereto. For example, the SOC may be presumed based on an open circuit voltage (OCV) that is in relatively good correlation with the SOC.

(2) Log Data

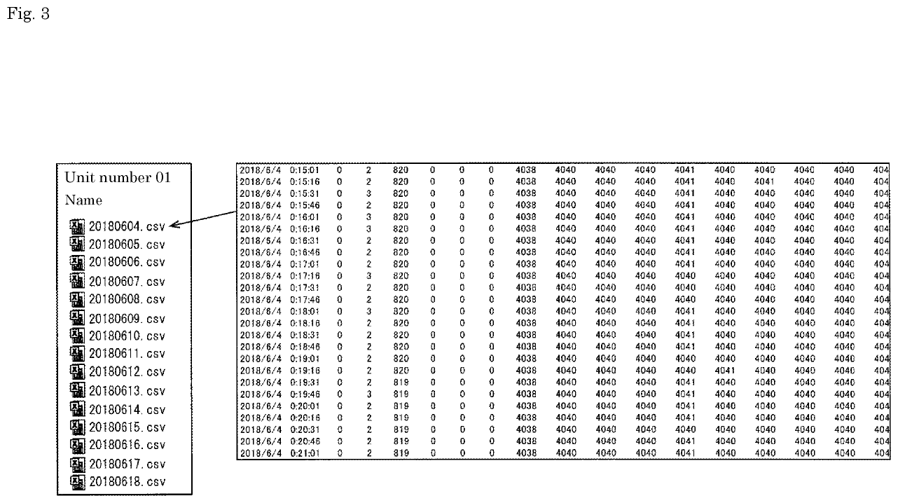

An example of the log data stored in the storage medium 24 will be described with reference to FIG. 3. Here, the log data for the energy storage unit 9 with the unit number 01 is used as the example. The log data is written to a log file that is different for each day. The log file has, as its file name, a date that the log data is written.

The log data includes data such as the date and time, the temperature value, the SOC, the current value, the voltage value of each of the battery cells 11, the voltage value of each of the energy storage modules 10 (the voltage between both ends of the assembled battery 15), and the alarm information. The data above is written to the log file in chronological order. The log data is in comma separated values (CSV) format. However, the data format is not limited thereto, and is appropriately optional.

(3) Flow of steps to follow at occurrence of problem with energy storage apparatus

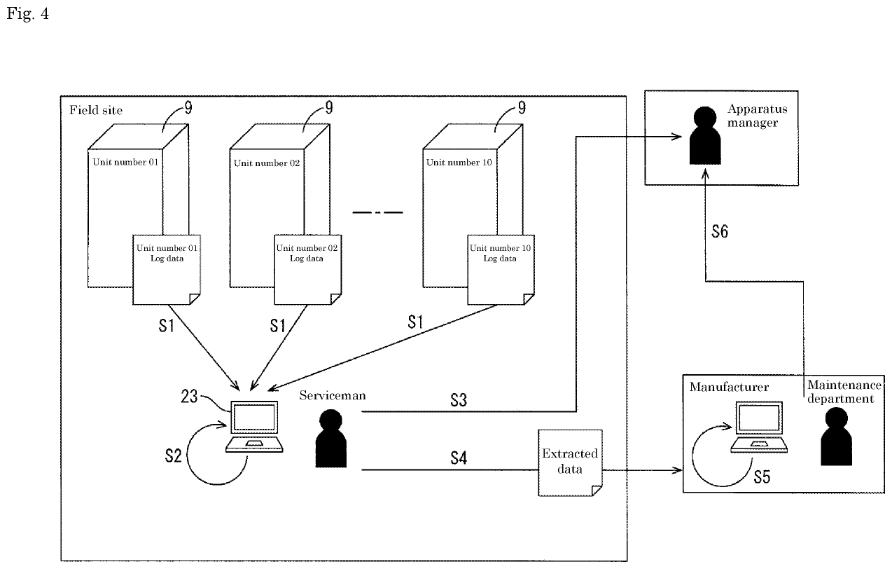

A flow to follow (flow of troubleshooting) at occurrence of some problem with the energy storage apparatus 1 will be described with reference to FIG. 4. When some problem occurs with the energy storage apparatus 1, an apparatus manager of the energy storage apparatus 1 reports to a manufacturer of the energy storage apparatus 1 that the energy storage apparatus 1 has some problem. On reception of the report, maintenance department of the manufacturer dispatches a serviceman to a site where the energy storage apparatus 1 is installed (hereinafter, will be referred to as a field).

The service man, having been dispatched to the field, collects the storage medium 24 from each of the energy storage units 9, and stores the log data stored in the storage medium 24 (that has been collected) in a personal computer (PC) 23 (51). The PC 23 is an example of a computer. Subsequently, the serviceman analyzes the log data stored in the PC 23, so as to presume an abnormal one of the battery cells 11 (S2). As will be described in detail later, the log data is analyzed based on a maintenance program.

When the serviceman has presumed the abnormal one of the battery cells 11, the serviceman describes a cause and troubleshooting to the apparatus manager (S3). On the other hand, when the serviceman has presumed multiple causes and thus struggles to presume the abnormal one of the battery cells 11, the serviceman transmits the log data to the maintenance department of the manufacturer via the communication network, e.g., the Internet or a telephone line (S4). As will be described in detail later, in this embodiment, the serviceman does not transmit all the log data but the log data extracted based on the maintenance program (extracted data). On reception of the log data, the maintenance department analyzes the log data to presume the cause (S5), and describes to the apparatus manager the cause and the troubleshooting (S6).

(4) Maintenance Program

The maintenance program (cell voltage checker) is configured to cause the PC 23 to execute an extraction step and an output step. In the extraction step, the PC 23 extracts, from the log data for each of the battery cells 11 in each of the energy storage units 9, the log data for the battery cell 11 in accordance with a sequential order of series connection that the serviceman has specified. In the output step, the PC 23 outputs the log data extracted in the extraction step.

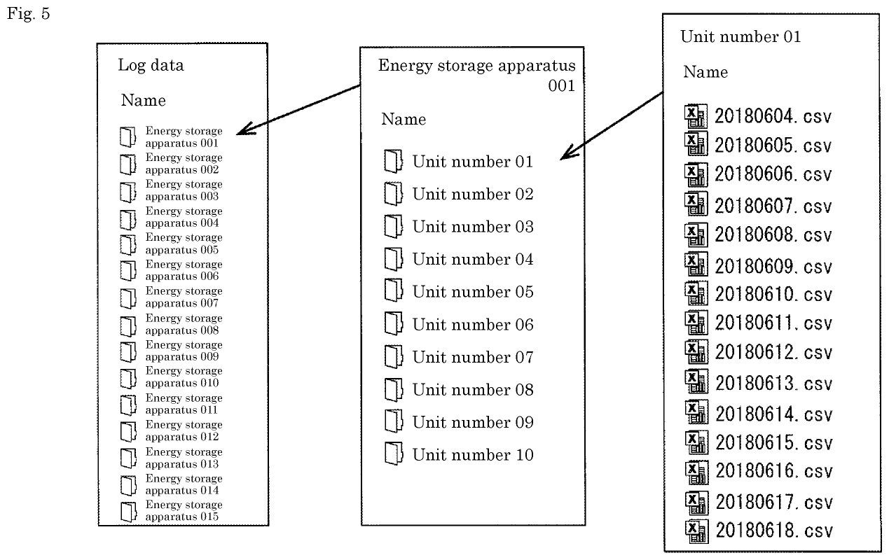

First, a folder configuration of the PC 23 will be described with reference to FIG. 5. The PC 23 includes a log data folder. The log data folder includes a folder for each of the energy storage apparatuses 1. The folder for each of the energy storage apparatuses 1 is provided with one of unit numbers 01 to 10. In the folder provided with each of the unit numbers, the log data, which has been copied from the log data stored in the storage medium 24, is stored; and the storage medium 24 has been collected from the energy storage unit 9 with the corresponding unit number.

Here, an example, in which the log data is stored in the PC 3 as a file, is described. Alternatively, the log data may be registered in a database that a database program (executed by the PC 23) manages.

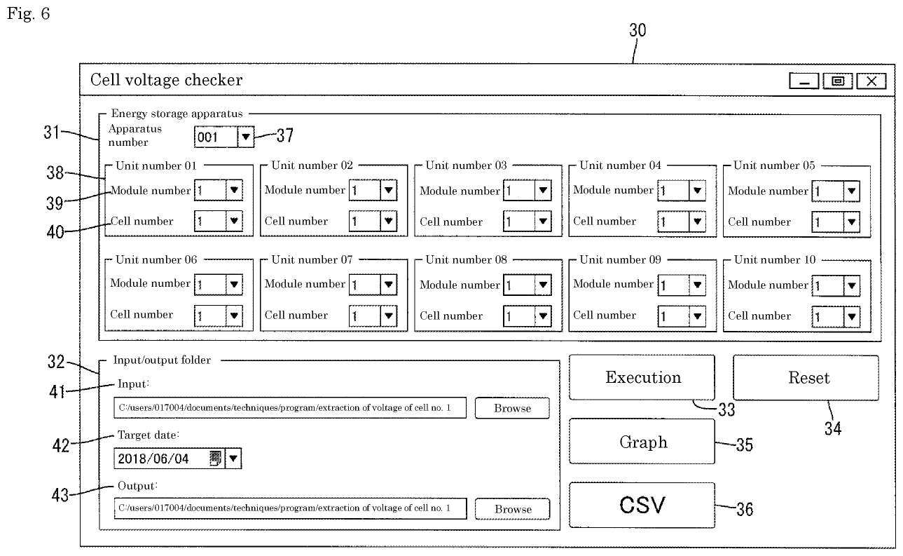

Next, the maintenance program will be described with reference to FIGS. 6 to 10. When the maintenance program is executed, a set screen 30 is displayed on a display unit of the PC 23 as illustrated in FIG. 6. The log data for each of the battery cells 11 has been stored in the PC 23; and on the set screen 30, the log data to be extracted from the log data stored in the PC 23 is to be specified. The set screen 30 includes an energy storage apparatus area 31, an input/output folder area 32, and various buttons (an execution button 33, a reset button 34, a graph button 35, and a CSV button 36), and others.

In the energy storage apparatus area 31, a condition to extract the log data is to be specified. The energy storage apparatus area 31 includes an apparatus number column 37 and ten unit number areas 38 (provided with the unit numbers 01 to 10). In the apparatus number column 37, a number provided to the energy storage apparatus 1 is to be specified. Each of the unit number areas 38 includes a module number column 39 and a cell number column 40. In the module number column 39, a sequential order of series connection of the energy storage modules 10 in the corresponding energy storage unit 9 is to be specified. In the cell number column 40, the sequential order of series connection of the battery cells 11 in the corresponding energy storage module 10 is to be specified.

The input/output folder area 32 includes an input column 41, a target date column 42, and an output column 43. In the input column 41, a path (directory) of the log data folder is to be specified. In the target date column 42, the date for the log data (to be extracted) is to be specified. The log data that has been extracted is written to a log file; and in the output column 43, a folder, in which the log file is to be stored, is to be specified.

The execution button 33 is used to execute extraction of the log data. When the execution button 33 has been pressed down, the log data, which conforms to conditions specified on the set screen 30, is extracted from the log data stored in the PC 23 (an example of the extraction step). As has been described above, the log data includes the date and time, the temperature value, the SOC, the current value, the voltage value of each of the battery cells 11, the voltage value of each of the energy storage modules 10, the alarm information, and others. Here, the maintenance program extracts not all the log data above but only the date and time along with the voltage value of the corresponding battery cell 11. The log data that has been extracted is written to a temporary file. Alternatively, the log data that has been extracted may be stored in a RAM of the PC 23.

The reset button 34 is used to reset each of the conditions set on the set screen 30 to an initial value (e.g., 1).

When the execution button 33 has been pressed down, the graph button 35 and the CSV button 36 are enabled.

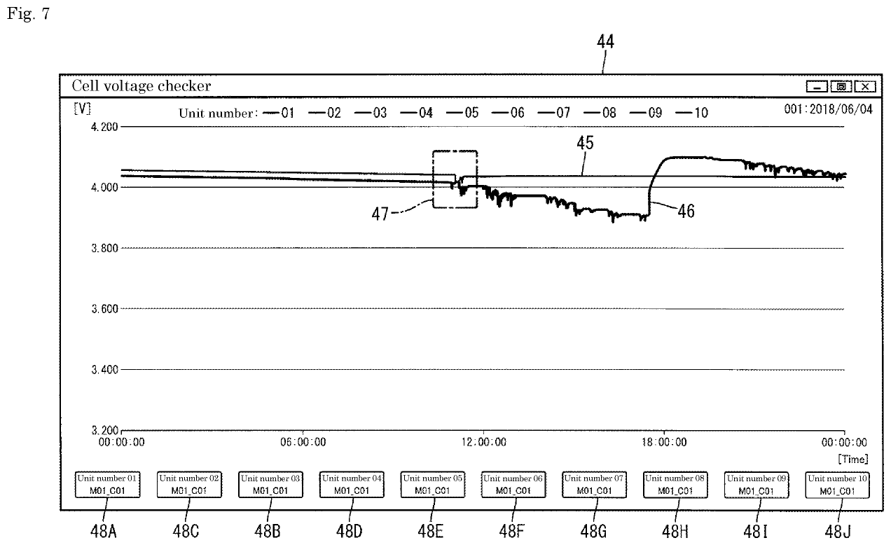

When the graph button 35 has been pressed down, a graph screen 44 is displayed as illustrated in FIG. 7 (an example of the output step). The graph screen 44 displays a graph illustrating temporal changes of the log data that has been extracted (voltage value of the battery cell 11 specified). On the graph screen 44, a solid line 45 represents a graph of the battery cell 11 specified in one of the energy storage units 9, with the unit number 04. A solid line 46 represents graphs of the battery cells 11 in the others of the energy storage units 9. Here, the battery cells 11 in the others of the energy storage units 9 are respectively represented in different graphs. In the example of FIG. 7, however, behaviors of the battery cells 11 in the others of the energy storage units 9 are substantially identical and thus, these graphs overlap each other. Accordingly, in FIG. 7, the solid line 46 collectively represents these graphs.

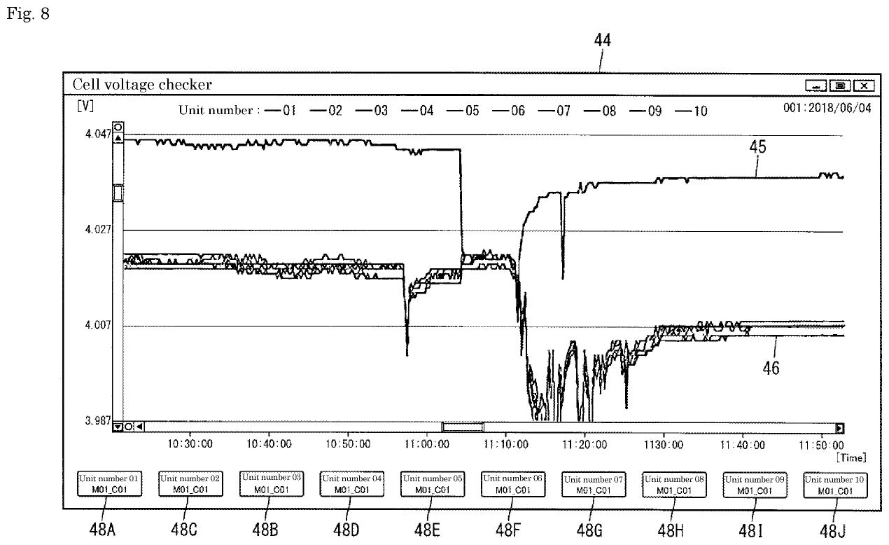

FIG. 8 illustrates the graph screen 44 in a state where a region 47 defined by a rectangular frame in FIG. 7 is enlarged. On the graph screen 44, the serviceman is allowed to specify any region to be enlarged. When a region to be enlarged has been specified, the maintenance program displays the region enlarged.

As illustrated in FIGS. 7 and 8, in a lower region of the graph screen 44, a plurality of buttons 48 (buttons 48A to 49J) are arranged and displayed horizontally. On each of the plurality of buttons 48, texts are displayed as a button name, and the texts represent the corresponding unit number, the sequential order of series connection of the energy storage modules that has been specified in the module number column 39, and the sequential order of series connection of the battery cells 11 that has been specified in the cell number column 40. Each of the plurality of buttons 48 is used to switch between display and hiding of the graph for the energy storage unit 9 displayed on the corresponding button 48; and thus, whenever each of the plurality of buttons 48 is pressed down, the graph for the energy storage unit 9 displayed on the corresponding button 48 is to be hidden or displayed.

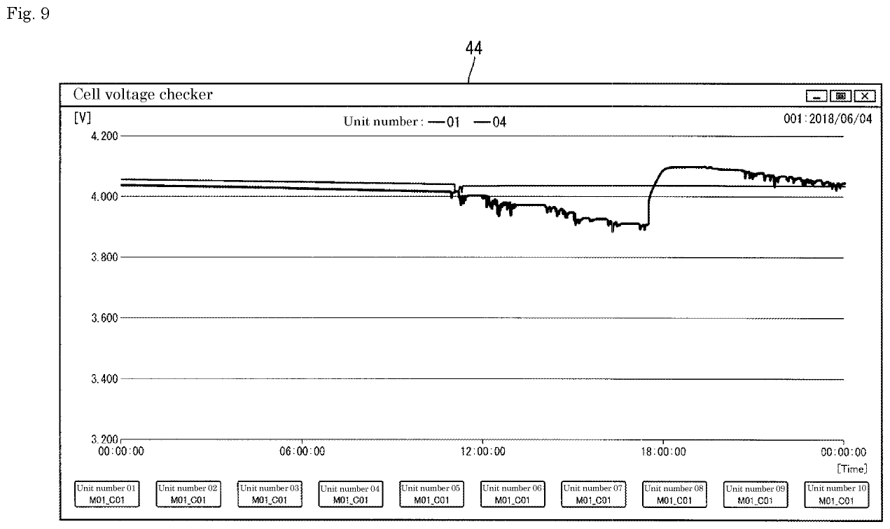

For example, when requiring the graphs for the energy storage units 9 with the unit numbers 01 and 04 only, a user needs to press down, on the graph screen 44, the button 48B (with the unit number 02), the button 48C (with the unit number 03), and the buttons 48E to 48J (with the unit numbers 05 to 10). When these buttons 48 have been pressed down, as illustrated in FIG. 9, the graphs for the energy storage units 9 corresponding to these buttons 48 are hidden.

When the CSV button 36 has been pressed down, the log data, which has been written to the temporary file, is written to the CSV file for data output (an example of the output step), and is stored in the folder that has been specified in the output column 43.

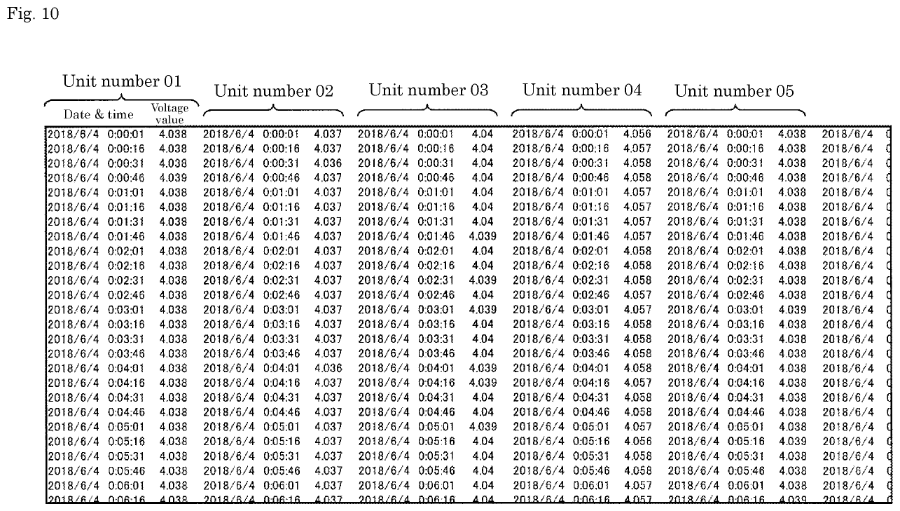

FIG. 10 shows an example of the CSV file for data output. In the CSV file for data output, from left to right in a direction of row (horizontal direction), the log data for the battery cell 11 in the energy storage unit 9 with the unit number 01, the log data for the battery cell 11 in the energy storage unit 9 with the unit number 02, the log data for the battery cell 11 in the energy storage unit 9 with the unit number 03, and up until the log data for the battery cell 11 in the energy storage unit 9 with the unit number 10 are sequentially written in. The log data for the battery cell 11 specified in each of the energy storage units 9 includes two pieces of data representing the date and time along with the voltage value of the corresponding battery cell 11; the two pieces of data are written in a direction of column (vertical direction) in chronological order. The log data are in the CSV format. However, the data format is not limited thereto, and is appropriately optional.

(5) Analysis of log data based on maintenance program

An analysis of the log data based on the maintenance program will be described with reference to FIG. 6. On the set screen 30, the serviceman specifies, in each of the unit number areas 38, the same number in the module number column 39 and the same number in the cell number column 40. In each of the unit number areas 38, the number to be specified in the module number column 39 may be any one of 1 to 15, as long as the same number is specified for each of the energy storage units 9. Similarly, in each of the unit number areas 38, the number to be specified in the cell number column 40 may be any one of 1 to 12, as long as the same number is specified for each of the energy storage units 9. With this configuration, from each of the energy storage units 9, the voltage value of the battery cell 11 in accordance with the same sequential order of series connection is extracted.

In the examples of FIGS. 7 and 8, an anomaly is assumed to occur with one of the battery cells 11 in the energy storage unit 9 with the unit number 04. As illustrated in FIGS. 7 and 8, in the energy storage unit 9 (unit number 04) including the abnormal one of the battery cells 11, whether the battery cell 11 specified in the energy storage unit 9 is normal or abnormal, the graph for the log data for the battery cell 11 specified tends to differ from the other graphs, which correspond to the graphs for the log data for the battery cells 11 specified in the other energy storage units 9 in accordance with the same sequential order of series connection as the battery cell 11 specified. Accordingly, these graphs are compared such that the battery cell 11 exhibiting a behavior different from those of the other battery cells 11 is identified (an example of a comparison step). With this configuration, it is possible to identify at high accuracy the energy storage unit 9 including the abnormal one of the battery cells 11 (an example of a determination step).

Having identified the energy storage unit 9 where the anomaly has occurred, the serviceman proceeds to a detailed analysis. In the detailed analysis, the serviceman analyzes the log data for the battery cells 11 in the energy storage unit 9 where the anomaly has occurred, so as to presume the abnormal one of the battery cells 11. When the serviceman has presumed the abnormal one of the battery cells 11, the serviceman describes the cause and the troubleshooting to the apparatus manager (S3 as has been described above).

On the other hand, when the serviceman has presumed multiple causes and thus struggles to identify the energy storage unit 9 where the anomaly has occurred, or when the serviceman has identified the energy storage unit 9 where the anomaly has occurred but struggles to presume the abnormal one of the battery cells 11, the serviceman presses down the CSV button 36 to write the log data (that has been extracted) to the CSV file for data output. Subsequently, the serviceman transmits the CSV file to the maintenance department of the manufacturer (S4 as has been described above, an example of a transmission step).

(6) Effects of foregoing embodiment

With the maintenance method according to the first embodiment, instead of going through an analysis of each individual one of the log data for a large number of the battery cells 11, by comparing the log data for the battery cells 11 that are respectively in accordance with the same sequential order of series connection in the energy storage units, the serviceman may identify, based on a small amount of data, the energy storage unit 9 where the anomaly has occurred. Accordingly, even when the serviceman is not very experienced or knowledgeable, it is possible to identify the energy storage unit 9 where the anomaly has occurred at high accuracy and in speedy manner. Having identified the energy storage unit 9 where the anomaly has occurred at high accuracy and in speedy manner, the serviceman proceeds without delay to the subsequent detailed analysis. With this configuration, when some problem occurs with the large scale energy storage apparatus 1, it is highly possible to restore the energy storage apparatus 1 in speedy manner, regardless of the knowledge or experience of the serviceman.

With the maintenance method for the energy storage apparatus 1 according to the first embodiment, the log data are stored in the storage medium 24, and the log data stored in the storage medium 24 are to be compared. With this configuration, despite difficulty in monitoring the energy storage apparatus 1 remotely, and even when the serviceman is not very experienced or knowledgeable, it is highly possible to identify the energy storage unit 9 where the anomaly has occurred on the field, at high accuracy, and in speedy manner. Accordingly, the maintenance method is suitably applied to an energy storage apparatus, in a situation where it is difficult to remotely monitor the energy storage apparatus.

With the maintenance method according to the first embodiment, the serviceman transmits to the maintenance department the log data for the battery cells 11 of the energy storage units 9 in accordance with the same sequential order of series connection. Thus, the log data transmitted here is smaller in amount than all the log data. Additionally, the serviceman transmits to the maintenance department only the log data to be analyzed, thereby facilitating the maintenance department to provide more efficient performances. Accordingly, it is highly possible to restore the energy storage apparatus 1 in speedy manner.

With the maintenance program according to the first embodiment, when some problem occurs with the (large scale) energy storage apparatus 1, it is highly possible to restore the energy storage apparatus 1 in speedy manner, regardless of the knowledge or experience of the serviceman.

In the maintenance program according to the first embodiment, the log data corresponds to the voltage values. At normal times, the voltage values are smaller in amount of instantaneous change than the current values and thus, the log data is less prone to vary according to timing of comparing the log data. Normally, the voltage value varies only when some anomaly has occurred and thus, it is easier to determine whether the condition is normal or not based on the voltage value, rather than based on the current value or the temperature value.

With the maintenance program according to the first embodiment, the log data extracted is to be displayed on the display unit, thereby clearly showing a difference between the log data for the normal one and the log data for the abnormal one. For example, when the log data for each of the battery cells 11 is displayed in a graph, the log data for the abnormal one of the battery cells 11 clearly shows the difference from the log data for the normal ones of the battery cells 11. With this configuration, it is easier to identify the energy storage unit 9 where the anomaly has occurred at high accuracy and in speedy manner.

With the maintenance program according to the first embodiment, by switching between the display and the hiding of the log data for the battery cell 11 selected, it is easier to identify the energy storage unit 9 where the anomaly has occurred at high accuracy and in speedy manner.

With the maintenance program according to the first embodiment, the log data extracted is to be written to the CSV file for data output. Thus, the CSV file, which the serviceman transmits to the maintenance department, is reduced in amount. Additionally, the serviceman transmits to the maintenance department only the log data to be analyzed, thereby facilitating the maintenance department to provide more efficient performances. Accordingly, it is highly possible to restore the energy storage apparatus 1 in speedy manner.

<Second Embodiment>

In the maintenance method according to the foregoing first embodiment, the log data for the battery cells 11 are compared, while in a maintenance method according to a second embodiment, the log data for the energy storage modules 10 are compared.

Specifically, the set screen 30 according to the foregoing first embodiment includes the module number column 39 and the cell number column 40; and when the sequential order of series connection has been specified in these columns, the sequential order of series connection of the battery cells 11 is specified. On the other hand, a set screen 30 (not illustrated) according to the second embodiment includes the module number column 39 but does not include the cell number column 40. Thus, on the set screen 30 according to the second embodiment, only the sequential order of series connection of the energy storage modules 10 is specified. Then, the log data (the voltage value of the assembled battery 15) for the energy storage module 10 in accordance with the specified sequential order of series connection is to be extracted.

With the maintenance method according to the second embodiment, when some problem occurs with the (large scale) energy storage apparatus 1, it is highly possible to restore the energy storage apparatus 1 in speedy manner, regardless of the knowledge or experience of the serviceman.

With the maintenance method according to the second embodiment, the serviceman transmits to the maintenance department the log data for the energy storage module 10 of the energy storage units 9 in accordance with the same sequential order of series connection. Thus, the log data transmitted here is smaller in amount than all the log data. Additionally, the serviceman transmits to the maintenance department only the log data to be analyzed, thereby facilitating the maintenance department to provide more efficient performances. Accordingly, it is highly possible to restore the energy storage apparatus 1 in speedy manner.

With the maintenance program according to the second embodiment, when some problem occurs with the large scale energy storage apparatus 1, it is highly possible to restore the energy storage apparatus 1 in speedy manner, regardless of the knowledge or experience of the serviceman.

<Other Embodiments>

In all aspects of the foregoing embodiments, it is understood that a maintenance method and a maintenance program according to the present invention is not limited thereto; and thus, various changes may be made within the scope of claims of the present invention. For example, in addition to configurations of one embodiment, configurations of any other embodiments may be exhibited, or the configurations of the one embodiment may be partially replaced with the configurations of any other embodiments or any known techniques. Alternatively, the configurations of the one embodiment may be partially deleted. Still alternatively, in addition to the configurations of the one embodiment, any known techniques may be exhibited.

(1) In the foregoing embodiments, an energy storage apparatus 1 mounted to a port/harbor AGV has been described as an example of an energy storage apparatus, the remote monitoring of which is not possible; but the energy storage apparatus is not limited thereto. For example, the energy storage apparatus, the remote monitoring of which is not possible, may be used for a power supply system that is installed to supply power in a mountainous area, a remote island, or others.

(2) In the foregoing embodiments, the energy storage apparatus 1 has been described as an example of the energy storage apparatus, the remote monitoring of which is not possible. Alternatively, the energy storage apparatus may be remotely monitored.

(3) In the foregoing first embodiment, as an example, the serviceman specifies, on the set screen 30, a sequential order of the energy storage modules 10 and a sequential order of series connection of the battery cells 11. Alternatively, these sequential orders of series connections may be previously fixed and set in the maintenance program. Each of the sequential orders of series connections fixed and set in the maintenance program is an example of a predetermined sequential order of series connection. The same applies to the second embodiment.

(4) In the foregoing first embodiment, as an example, in each of the energy storage units 9, the sequential order of series connection of the energy storage modules 10 and the sequential order of series connection of the battery cells 11 are specified on the set screen 30. Alternatively, in an entire part of the energy storage apparatus 1, the sequential order of series connection of the energy storage modules 10 and the sequential order of series connection of the battery cells 11 may be specified; and the sequential orders of series connections, which have been specified in the entire part of the energy storage apparatus 1, may be commonly applied to each of the energy storage units 9. The same applies to the second embodiment.

(5) In the foregoing embodiments, a voltage value is used as an example of the log data; but the log data is not limited thereto, and may thus be a current value, a temperature value, an SOC, or others.

(6) In the foregoing second embodiment, as an example, the log data for the energy storage modules 10 (voltage values of the assembled batteries 15) are extracted. On the other hand, the system may be configured to receive the user's option of whether to extract the log data for the battery cells 11 (voltage value of each of the battery cells 11) or the log data for the energy storage modules 10, and configured to extract the log data in response to the user's option.

(7) The comparison step, the determination step, and the transmission step, each described in the foregoing first embodiment, may be executed based on the maintenance program. The same applies to the second embodiment.

(8) In the foregoing embodiments, the energy storage device is a lithium ion battery, but the energy storage device is not limited to thereto. The energy storage device may be, for example, a capacitor accompanying an electrochemical reaction.

1. A maintenance method for an energy storage apparatus including a plurality of energy storage units that are connected in parallel to each other, each of the energy storage units including a plurality of energy storage devices that are connected in series, the maintenance method comprising:
a comparison step of comparing log data for one of the energy storage devices in each of the energy storage units, which is at a same sequential order of series connection; and
a determination step of, based on a comparison result of the comparison step, determining which one of the energy storage units has an anomaly.

2. A maintenance method for an energy storage apparatus including a plurality of energy storage units that are connected in parallel to each other, each of the energy storage units including a plurality of energy storage modules that are connected in series, the maintenance method comprising:
a comparison step of comparing log data for one of the energy storage modules in each of the energy storage units, which is at a same sequential order of series connection; and
a determination step of, based on a comparison result of the comparison step, determining which one of the energy storage units has an anomaly.

3. The maintenance method for the energy storage apparatus according to claim 1, wherein:
the energy storage apparatus stores the log data in a storage medium, and
in the comparison step, the log data stored in the storage medium are compared with each other.

4. The maintenance method for the energy storage apparatus according to claim 1, further comprising a transmission step of transmitting to a maintenance department the log data for the one of the energy storage devices in each of the energy storage units, which is at the same sequential order of series connection.

5. The maintenance method for the energy storage apparatus according to claim 2, further comprising a transmission step of transmitting to a maintenance department the log data for the one of the energy storage modules in each of the energy storage units, which is at the same sequential order of series connection.

6. A maintenance program for an energy storage apparatus including a plurality of energy storage units that are connected in parallel to each other, each of the energy storage units including a plurality of energy storage devices that are connected in series,
the maintenance program causing a computer to execute:
an extraction step of, from log data for each of the energy storage devices in each of the energy storage units, extracting log data for one of the energy storage devices at a predetermined sequential order of series connection or a specified sequential order of series connection; and
an output step of outputting the log data that has been extracted in the extraction step.

7. A maintenance program for an energy storage apparatus including a plurality of energy storage units that are connected in parallel to each other, each of the energy storage units including a plurality of energy storage modules that are connected in series,
the maintenance program causing a computer to execute:
an extraction step of, from log data for each of the energy storage modules in each of the energy storage units, extracting log data for one of the energy storage modules at a predetermined sequential order of series connection or a specified sequential order of series connection; and
an output step of outputting the log data that has been extracted in the extraction step.

8. The maintenance program for the energy storage apparatus according to claim 6, wherein the log data comprises a voltage value.

9. The maintenance program for the energy storage apparatus according to claim 6, wherein the output step comprises a step of displaying on a display unit the log data that has been extracted in the extraction step.

10. The maintenance program for the energy storage apparatus according to claim 9, further causing the computer to execute a switch step of switching between display and hiding of log data selected from the log data that has been displayed on the display unit.

11. The maintenance program for the energy storage apparatus according to claim 6, wherein the output step comprises a step of writing to a file the log data that has been extracted in the extraction step.

12. The maintenance method for the energy storage apparatus according to claim 2, wherein:
the energy storage apparatus stores the log data in a storage medium, and
in the comparison step, the log data stored in the storage medium are compared with each other.

13. The maintenance program for the energy storage apparatus according to claim 7, wherein the log data comprises a voltage value.
